(19) United States
(12) Patent Application Publication
(10) Pub. No.: US 2025/0391677 A1
(43) Pub. Date: Dec. 25, 2025

(54) ETCHING METHOD AND ETCHING APPARATUS

(71) Applicant: Tokyo Electron Limited, Tokyo (JP)

(72) Inventors: Yasuo ASADA, Nirasaki City (JP); Woonghyun JEUNG, Nirasaki City (JP); Jeongchan LEE, Nirasaki City (JP)

(21) Appl. No.: 19/317,589

(22) Filed: Sep. 3, 2025

Related U.S. Application Data
(63) Continuation of application No. PCT/JP2024/003636, filed on Feb. 5, 2024.

(30) Foreign Application Priority Data
Mar. 13, 2023 (JP) 2023-038904

(51) Int. Cl. H01L 21/67; H01L 21/311

(52) U.S. Cl. CPC H01L 21/67069; H01L 21/31116

(57) ABSTRACT

An etching method includes a first storage process of supplying a first etching gas to a first gas supply path and storing the first etching gas in a first storage to increase an internal pressure of the first storage, a second storage process of supplying a second etching gas to a second gas supply path and storing the second etching gas in a second storage to increase an internal pressure of the second storage, a first supply process of supplying the first etching gas from the first storage into the processing container in a first period, and a second supply process of supplying the second etching gas from the second storage into the processing container in a second period, wherein at least one of a start point or an end point of the second period is set to be different from that of the first period.

### CROSS-REFERENCE TO RELATED APPLICATION

The application is a Bypass Continuation application of PCT International Application No. PCT/JP2024/003636, filed on Feb. 5, 2024 and designating the United States, the international application being based upon and claiming the benefit of priority from Japanese Patent Application No. 2023-038904, filed on Mar. 13, 2023, the entire content of which is incorporated herein by reference.

### TECHNICAL FIELD

The present disclosure relates to an etching method and an etching apparatus.

### BACKGROUND

In processing a substrate such as a semiconductor wafer (hereinafter referred to as a wafer), a gas having been temporarily stored in a tank may be discharged into a processing container. Patent Document 1 discloses discharging He gas, HCl gas, and SF₆ gas, which have been stored in tanks as described above, to perform an etching process on a substrate for manufacturing a flat panel display (FPD).

### PRIOR ART DOCUMENT

### Patent Document

Patent Document 1: Japanese Patent No. 5235293

### SUMMARY

An etching method according to the present disclosure includes a first storage process of supplying the first etching gas to a first gas supply path, storing the first etching gas in and pressurizing a first storage, a second storage process of supplying the second etching gas to a second gas supply path, storing the second etching gas in and pressurizing a second storage, a first supply process of supplying the first etching gas from the first storage into the processing container in a first period, and a second supply process of supplying the second etching gas from the second storage into the processing container in a second period, wherein at least one of a start point or an end point of the second period is different from at least one of a start point or an end point of the first period, so that there is a period during which only one of the first etching gas or the second etching gas is supplied into the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional side view of an etching apparatus according to one embodiment of the present disclosure.

FIG. 2 is a plan view of a wafer.

FIG. 3 is a plan view of a wafer.

FIG. 4 is a chart illustrating supply times of gases.

FIG. 5 is a longitudinal cross-sectional side view of a wafer.

FIG. 6 is a longitudinal cross-sectional side view of the wafer.

FIG. 7 is an explanatory diagram illustrating a result of an evaluation test.

FIG. 8 is an explanatory diagram illustrating a result of an evaluation test.

FIG. 9 is an explanatory diagram illustrating a result of an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

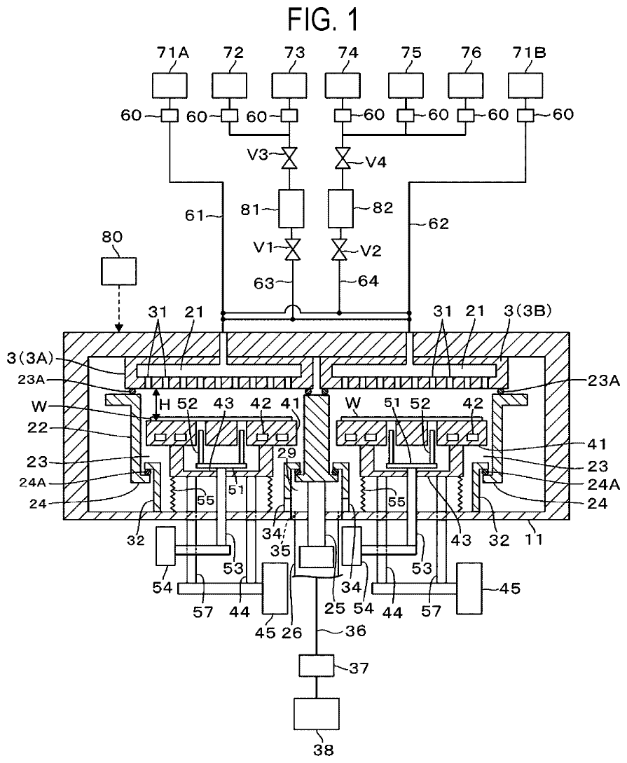

An etching apparatus 1, which is one embodiment of an etching apparatus according to the present disclosure and performs an etching method according to the present disclosure, will now be described with reference to a longitudinal cross-sectional side view of FIG. 1. In the etching apparatus 1, etching is performed by accommodating a wafer W as a circular substrate in a processing container 11, setting an inside of the processing container 11 to be a desired pressure as a vacuum atmosphere, and supplying a halogen-containing gas as a first etching gas and a basic gas as a second etching gas. Specifically, in this example, etching a SiOx (silicon oxide) film 91 in a surface of the wafer W is performed using a HF (hydrogen fluoride) gas as the halogen-containing gas and a mixed gas of NH₃ (ammonia) gas and an amine gas as the basic gas. As the amine gas, for example, trimethylamine (TMA) gas is used.

Therefore, ammonium fluorosilicate ((NH₄)₂SiF₆, AFS)), which is a reaction product of HF and NH₃ acting on SiOx, and a reaction product of HF and TMA acting on SiOx are generated on the surface of the wafer, and etching is performed by sublimation of these reaction products. During such etching, no plasma is generated around the wafer W.

The HF gas and the basic gas are stored in tanks 81 and 82 in a state in which interiors of the tanks 81 and 82 are pressurized, and valves V1 and V2 on a downstream side of the tanks 81 and 82 are opened to supply the gases into the processing container 11. As will be described in detail later, in order to obtain a desired etching amount, gas supply cycles are set such that supplying the HF gas and the basic gas is repeated. In each cycle, a period during which the HF gas is supplied into the processing container 11 and a period during which the basic gas is supplied into the processing container 11 are set to be offset from each other.

Hereinafter, a configuration of the apparatus will be described in detail. Wafers W are accommodated horizontally side by side in the processing container 11. Etching is collectively performed for the two wafers W. The wafers W are processed in processing spaces 21 that are partitioned from each other. In the processing container 11, a processing space former 22 for forming the processing spaces 21 is provided. The processing space former 22 is configured such that through-holes 23, which penetrate in a vertical direction, are provided in a horizontally elongated block and distanced horizontally from each other. Lower edges of circumferential surfaces forming the through-holes 23 form protruding edges 24 that protrude inward.

A horizontally central bottom of the processing space former 22 is connected to an elevator 26 provided outside the processing container 11 via a support column 25 penetrating a bottom wall of the processing container 11, so that the processing space former 22 can move up and down between an upper position and a lower position in the processing container 11. In addition, a bellows (not shown) surrounding the support column 25 is provided outside the processing container 11. Thus, a gap formed between the support column 25 and a bottom wall of the processing container 11 is sealed by moving the support column 25 up and down.

On a ceiling of the processing container 11, two shower plates 3 having a circular shape in a plan view are provided. The shower plates 3 are positioned above the through-holes 23 of the processing space former 22, respectively. In some cases, the two shower plates 3 are distinguished and referred to as reference symbols 3A and 3B, respectively. A gas supplied to central portions of the shower plates 3 via each pipe to be described later is discharged downward from discharge ports 31, which are formed in lower surfaces of the shower plates 3 in a distributed manner, via flow paths in the shower plates 3.

Cylindrical bodies 32 are erected from left and right portions of the bottom wall of the processing container 11, respectively. When the processing space former 22 is positioned at the upper position, O-rings 23A provided on opening edges of the through-holes 23 are brought into close contact with peripheral portions of the lower surfaces of the shower plates 3, and O-rings 24A provided on the protruding edges 24 are brought into close contact with flanges formed at upper edge portions of the cylindrical bodies 32. Thus, the processing spaces 21 described above are formed. Among spaces surrounded by the processing space former 22 and the shower plates 3, the processing spaces 21 are regions located above stages 41 described later.

Through-holes 34 are formed in side walls of the cylindrical bodies 32. In the horizontally central portion of the bottom wall of the processing container 11, an exhaust port 35 is opened at a position spaced rearward from the support column 25. Outside the bottom wall, an exhaust pipe 36 is connected to the exhaust port 35 such that an upstream end of the exhaust pipe 36 is open toward the exhaust port 35. A downstream end of the exhaust pipe 36 is connected to an exhauster 38 configured by a vacuum pump and the like, via a valve 37. By adjusting an open degree of the valve 37, pressures in the processing spaces 21 are regulated.

When the processing space former 22 is positioned at the lower position, a transfer port (not shown) provided in a front side of the processing container 11 is positioned above the processing space former 22. A transfer mechanism for the wafers W provided outside the processing container 11 enters the processing container 11 via the transfer port and is positioned above the through-holes 23 via the transfer port. Delivering the wafers W with respect to the stages 41 to be described later can be performed via pins 52 to be described later.

The stage 41 is provided in each of the through-holes. Upper surfaces of the stages 41 are horizontal planes and face the lower surfaces of the shower plates 3. In a plan view, central portions of the shower plates 3 are aligned with central portions of the wafers W placed on the upper surfaces of the stages 41. Fluid paths 42 to which temperature-controlled fluids are supplied are provided in the stages 41, so that temperatures of the wafers W placed on the stages 41 can be adjusted to a desired temperature. Partitions 43, which have concave shapes when viewed in a longitudinal cross-section, are provided to be connected to the lower surfaces of the stages 41, so that partitioned spaces are formed below the stages 41.

The partitions 43 are connected to elevators 45 provided outside the processing container 11 via support columns 44 extending downward through the bottom wall of the processing container 11, so that heights of the stages 41 can be changed. Therefore, when processing the wafers W, volumes of the processing spaces 21 can vary by changing a height H between the stages 41 and the shower plates 3. In order to quickly diffuse and exhaust a gas throughout the processing spaces 21, processing may be performed with the height H set to a relatively small value, for example, 40 mm or less.

Three pins 52 (only two are shown in the drawing), which are supported by each of support plates 51 provided in spaces formed by the partitions 43 and the lower surfaces of the stages 41 and extend upward in a vertical direction, are provided. The support plates 51 are connected to elevators 54 provided outside the processing container 11 via support columns 53 extending downward through the partitions 43 and the bottom wall of the processing container 11. Thus, the pins 52 can protrude from and retract into the upper surfaces of the stages 41, and as described above, the wafers W are delivered between the transfer mechanism and the stages 41. Reference numeral 55 in the drawing denotes bellows which surround the support columns 44 and 53 and connects the partitions 43 and the bottom wall of the processing container 11. The bellows 55 prevent airtightness inside the processing container 11 from being broken by gaps between the support columns 44 and 53 and the bottom wall of the processing container 11.

The etching apparatus 1 includes pipes 61, 62, 63, and 64. The pipes 61 and 62 are connected to the ceiling of the processing container 11 to supply gases from above to the central portions of the shower plates 3A and 3B, respectively. Further, upstream sides of the pipes 61 and 62 are connected to N₂ gas supplies 71A and 71B, respectively, via flow rate adjusters 60. The flow rate adjusters 60 are constituted by valves and mass flow controllers. The flow rate adjusters 60 switch between supply and stop of the gases to a downstream side of a flow path and adjust flow rates of the gases. Flow rate adjusters 60 provided in pipes to be described later other than the pipes 61 and 62 have the same configuration as the flow rate adjusters 60 provided in the pipes 61 and 62. N₂ (nitrogen) gas supplied from N₂ gas supplies 71 (71A and 71B) serves as a carrier gas for an etching gas and also as a purge gas for purging the interior of the processing container 11. During processing the wafers W, the N₂ gas is always supplied from the gas supplies 71A and 71B.

The pipes 63 and 64 are configured as gas paths in which storages are provided. The pipe 63 forms a first gas supply path, and the pipe 64 forms a second gas supply path. Downstream ends of the pipes 63 and 64 are connected to the ceiling of the processing container 11 to supply gases from above to the central portions of the shower plates 3A and 3B. The valve V1, the tank 81, and a valve V3 are provided in the pipe 63 in this order toward an upstream side. The pipe 63 branches into two branches on an upstream side of the valve V3. One of the branches is connected to a HF gas supply 72, which is a first gas supply, via the flow rate adjuster 60, and the other of the branches is connected to a N₂ gas supply 73 via the flow rate adjuster 60. N₂ gas supplied from the N₂ gas supply 73 is a dilution gas for the HF gas. The valve V3 is open in a period during which each gas is supplied to and stored in the tank 81, which is a first storage, and is closed in a period during which the valve V1, which is a first valve, is open, in order to prevent the gas stored in the tank 81 from backflowing through the pipe 63.

The valve V2, the tank 82, and a valve V4 are provided in the pipe 64 in this order toward an upstream side. The pipe 64 branches into three branches on an upstream side of the valve V4. Upstream ends of the branches are connected to a TMA gas supply 74, a NH₃ gas supply 75, and a N₂ gas supply 76 via the flow rate adjusters 60, respectively. The TMA gas supply 74 and the NH₃ gas supply 75 constitute a second gas supply. N₂ gas supplied from the N₂ gas supply 76 is a dilution gas for the NH₃ gas and the TMA gas. The valve V4 is open in a period during which each gas is supplied to and stored in the tank 82, which is a second storage, and is closed in a period during which the valve V2, which is a second valve, is open in order to prevent the gas stored in the tank 82 from backflowing through the pipe 64.

The etching apparatus 1 includes a controller 80 which is a computer. The controller 80 includes software, a memory, and a CPU. A command (individual steps) for processing the wafers W to be described later is built in a program. The program is stored in a non-transitory computer-readable storage medium such as a compact disk, a hard disk, a magneto-optical disk, a DVD, or the like, and installed in the controller 80. The controller 80 outputs control signals to individual components of the etching apparatus 1 according to the program to control operations of the individual components. Specifically, operation, such as discharging gases from the tanks 81 and 82 by opening and closing the valves V1 to V4, supplying gases to the tanks 81 and 82, adjusting the flow rates of gases supplied to the downstream side by the flow rate adjusters 60, moving the processing space former 22, the stages 41, and the pins 52 up and down by the elevators 26, 45, and 54, and adjusting the open degree of the valve 37, are controlled by the control signal.

As described above, the etching apparatus 1 performs etching such that the period during which the HF gas is supplied to the processing container 11 and the period during which the NH₃ gas and the TMA gas are supplied to the processing container 11 are offset from each other (at least one of supply start points or supply end points are offset from each other). In addition, since the etching apparatus 1 is configured as described above, the period during which the HF gas is supplied to the processing container 11 and the period during which the NH₃ gas and the TMA gas are supplied to the processing container 11 are periods during which the valves V1 and V2 are open, respectively. Therefore, opening and closing the valves V1 and V2 are controlled so that at least one of times at which the valves V1 and V2 are open or times at which the valves V1 and V2 are closed are offset from each other in the same cycle (in a period during which the HF gas and the basic gas are each supplied once).

A reason for setting the gas supply periods to be offset from each other as described above will now be described. In the etching apparatus 1, etching gases (HF gas, and NH₃ gas and TMA gas) are stored in the tanks 81 and 82, respectively, and in a state in which the interiors of the tanks 81 and 82 are pressurized, the valves V1 and V2 are opened to supply the gases to the processing container 11. Thus, the gases are diffused rapidly throughout the processing space 21, thereby improving throughput. Further, in order to improve the throughput, the valves V1 and V2 are quickly closed after being opened, so that the supply of the etching gases to the processing spaces 21 is stopped, and the gases are exhausted. In one cycle, a period during which each of the valves V1 and V2 is open is, for example, one second or less.

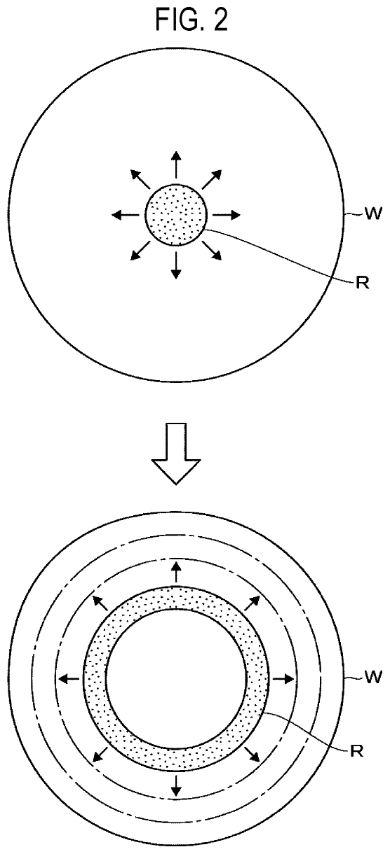

As shown in evaluation tests to be described later, when the gases are supplied while setting times at which the valves V1 and V2 are open to coincide with each other and times at which the valves V1 and V2 are closed to coincide with each other in the same cycle, etching amounts at central portions of the wafers W become greater than those at peripheral portions of the wafers W. An estimation of a mechanism for such an etching distribution will now be described with reference to FIG. 2, which is a plan view of a wafer W.

Each etching gas is introduced from a corresponding pipe to the central portion of the shower plate 3, that is, to a position above a central portion of the wafer W. Although the etching gas is dispersed in the shower plate 3, since the interiors of the tanks 81 and 82 have been pressurized, a relatively large amount of etching gas is supplied to the central portion of the wafer W with a flow momentum of when the etching gas is introduced to the shower plate 3. Since the processing space 21 is exhausted, the etching gas supplied to the central portion of the wafer W as described above flows toward an outer edge of the wafer W. However, since the valves V1 and V2 are closed quickly after being opened, each etching gas is supplied to the wafer W instantaneously. Therefore, when a region R is defined as a region in which a concentration of the etching gas is relatively high in a plan view, the region R rapidly changes from a state forming a circle at the central portion of the wafer W to a ring shape. As a diameter of the ring increases, the ring rapidly expands toward the outer edge of the wafer W.

When the period during which the HF gas is supplied to the wafer W and the period during which the basic gas (NH₃ gas+TMA gas) is supplied to the wafer W overlap and coincide with each other, the etching gases flow over the wafer W as described above. That is, the region R described with reference to FIG. 2 is formed by both the HF gas and the basic gas. Therefore, from a perspective of one etching gas of the HF gas and the basic gas, when the one etching gas is supplied to the central portion of the wafer W, a sufficient concentration of the other etching gas is present around the central portion of the wafer W. As a result, the reaction products described above are generated between these gases and the SiOx film 91 on the surface of the wafer W. That is, since the one etching gas reacts with the other etching gas and the SiOx film 91 before most of the each etching gas diffuses to the peripheral portion of the wafer W, the etching amount at the central portion of the wafer W becomes greater than that at the peripheral portion of the wafer W, as described above.

In order to suppress a difference in etching amount between the peripheral portion and the central portion of the wafer W to increase in-plane uniformity of the etching amounts in the wafer W, the etching apparatus 1 performs processing such that the period during which the HF gas is supplied into the processing container 11 and the period during which the basic gas is supplied into the processing container 11 are offset from each other. By setting the periods to be offset from each other as described above, from the perspective of one etching gas supplied to the central portion of the wafer W, a state in which a concentration of the other etching gas at the central portion is relatively low is formed. Thus, excessive reactions are suppressed from occurring at the central portion of the wafer W.

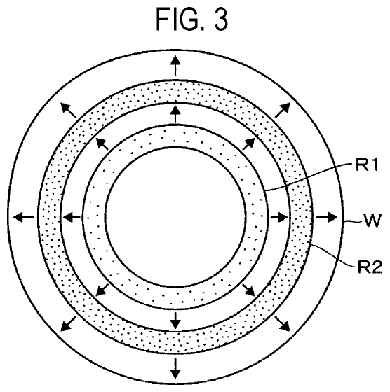

In addition, by setting the period during which the HF gas is supplied to the wafer W and the period during which the basic gas is supplied to the wafer W to be offset from each other as described above, etching can be promoted at positions away from the central portion of the wafer W. A mechanism that promotes the etching is estimated as follows. By setting the period during which the HF gas is supplied to the wafer W and the period during which the basic gas (NH₃ gas+TMA gas) is supplied to the wafer W to be offset from each other, it is possible to set a time when the region R (for convenience, referred to as region R1) in which the concentration of the HF gas is high is spread over the wafer W and a time when the region R (for convenience, referred to as region R2) in which the concentration of the basic gas is high is spread over the wafer W to be different from each other, as illustrated in FIG. 3.

When the supply periods of the HF gas and the basic gas are offset from each other slightly, as the region R and the region R2 are spread over the wafer W, the region R1 and the region R2 approach each other at a position deviating from the central portion of the wafer W, and the HF gas forming the region R1 and the basic gas forming the region R2 are mixed with each other. Therefore, a region in which concentrations of both the HF gas and the basic gas are high is formed on a peripheral portion deviating from the central portion in a radial direction of the wafer W, and etching is promoted in the region. As described above, when the gas supply periods are set to be offset from each other, it is possible to match the etching amounts in the central portion and the peripheral portion of the wafer W with each other, as compared to the case in which the supply periods of the gases are set to coincide with each other as shown in FIG. 2.

When the etching gases are supplied from the gas supplies into the processing container 11 for a relatively long period of time without being stored in the tanks 81 and 82, the etching gases, which are diffused in the shower plate 3 with relatively high uniformity, is supplied to the processing space 21, and are also diffused with relatively high uniformity in the processing space 21. Therefore, it is considered that in-plane uniformity of an etching distribution in the wafer W becomes relatively high. Accordingly, the present disclosure is effective particularly in the already described case in which etching gases are supplied within a short period of time by storing the etching gases in tanks (storages) and closing valves on downstream sides of the tanks quickly after opening the valves.

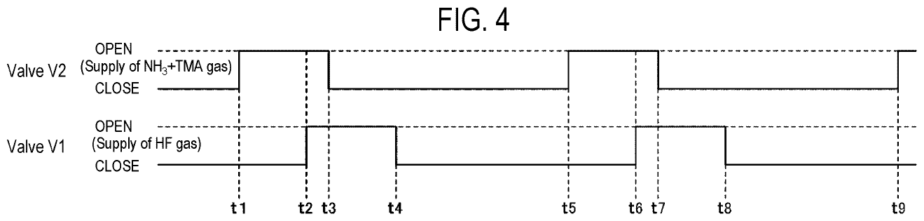

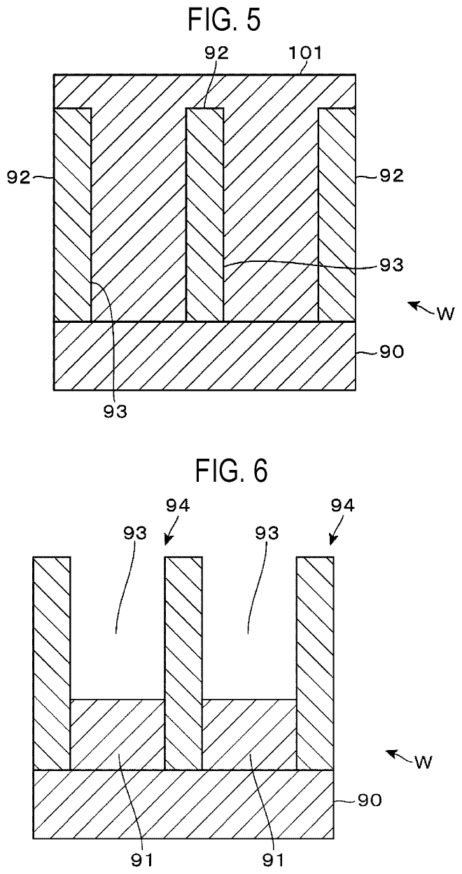

Next, a processing sequence for the wafer W in the etching apparatus 1 will be described with reference to a time chart of FIG. 4. The time chart shows opening and closing times of the valves V1 and V2. Accordingly, the time chart shows times at which the HF gas is supplied to the wafer W in the processing container 11 and times at which the NH₃ gas and the TMA gas are supplied. FIGS. 5 and 6 are longitudinal cross-sectional side views of a wafer W, and illustrate a state before etching and a state after completion of the etching, respectively. In the wafer W, a Si film 92 is formed on an underlayer film 90, and grooves 93 are formed in the Si film 92. The SiOx film 91 before etching is provided to cover the Si film 92 and enter the grooves 93.

In this example, etching is performed to remove the SiOx film 91 on the Si film 92 and also to remove a part of the SiOx film 91 in the grooves 93. That is, processing in this example includes etching the SiOx film 91 in a recess having a side wall formed by the Si film 92. During the etching, although both the SiOx film 91 and the Si film 92 are exposed from a surface of the wafer W, the SiOx film 91 is selectively etched between the SiOx film 91 and the Si film 92 by using the above-described etching gases. Further, as illustrated in FIG. 6, the etching is completed in a state in which a part of the SiOx film 91 remains in the grooves 93.

In a state in which the processing space formers 22 are positioned at the lower position, the two wafers W in a state shown in FIG. 5 are transferred from the outside of the processing container 11 to above the respective stages 41 by the not shown transfer mechanism. Thereafter, each wafer W is placed on the stage 41 via the pins 52 and a temperature of the wafer W is adjusted to a predetermined temperature, for example, −20 degrees C. to 150 degrees C. Further, the processing space formers 22 are positioned to the upper position to form the processing spaces 21 in the processing container 11. Furthermore, the stage 41 is positioned at a predetermined height, and the height H between the stage 41 and the lower surface of the shower plate becomes the above-described value. In a state in which N₂ gas is supplied into the processing container 11 from the gas supplies 71A and 71B, the exhauster 38 performs exhaustion and a pressure in the processing spaces 21 becomes 0.133 Pa to 666 Pa.

While the valves V1 and V2 are closed, the valves V3 and V4 are opened. Further, the HF gas and the N₂ gas are supplied from the gas supplies 72 and 73 to the tank 81, whereas the basic gas (NH₃ gas+TMA gas) and the N₂ gas are supplied from the gas supplies 74 to 76 to the tank 82. Thus, the interiors of the tanks 81 and 82 are pressurized. That is, a first storage process and a second storage process are performed. Thereafter, the valve V2 is opened (time t1 in the chart), and the gases (basic gas+N₂ gas) in the tank 82 are supplied to each processing space 21. As described above, since the interior of the tank 82 is pressurized, a relatively large amount of basic gas (NH₃ gas+TMA gas) is supplied to the central portion in the surface of the wafer W. Further, the basic gas flows toward the outer edge of the wafer W, and NH₃ and TMA are adsorbed to each portion in the surface of the wafer W.

At time t2, which is, for example, 0.3 seconds after time t1, the valve V1 is opened and the gases (HF gas+N₂ gas) in the tank 81 are supplied to each processing space 21. Since the HF gas is also supplied to the processing space 21 in a state in which the interior of the tank 81 is pressurized, a relatively large amount of HF gas is supplied to the central portion of the wafer W. By supplying the basic gas and the HF gas to the central portion of the wafer W as described above, the SiOx film 91 at the central portion reacts with these gases to generate the reaction products described above.

However, since the basic gas is supplied prior to the HF gas and begins to flow toward the outer edge of the wafer W, it is prevented that both the basic gas and the HF gas have high concentrations at the central portion of the wafer W. Thus, excessive modification of the SiOx film 91 (generation of the reaction products) at the central portion is prevented. Further, the HF gas supplied to the central portion of the wafer W flows toward the outer edge of the wafer W, so that HF is adsorbed to each portion in the surface of the wafer W and reacts with the SiOx film 91 together with the NH₃ and TMA, which have been adsorbed in advance. Thus, the reaction products are generated.

At time t3, which is, for example, 0.2 seconds after time t2, the valve V2 is closed and the supply of gases from the tank 82 to each processing space 21 is stopped. Subsequently, at time t4, which is, for example, 0.3 seconds after time t3, the valve V1 is closed and the supply of gases from the tank 81 to each processing space 21 is stopped. Even during time t3 to time t4, only one of the basic gas and the HF gas is supplied to the central portion of the wafer W, and it is prevented that both of these gases have high concentrations at the central portion of the wafer W. Therefore, excessive modification of the SiOx film 91 at the central portion of the wafer W is prevented. In addition, during time t1 to time t4, the region R1 where the concentration of the basic gas is relatively high and the region R2 where the concentration of the HF gas is relatively high expand toward the outer edge of the wafer W as described with reference to FIG. 3, the gases forming the regions are mixed on the peripheral portion of the wafer W, and reaction progresses relatively significantly at locations at which the gases are mixed.

After time t4, while the supply of the basic gas and the HF gas to the processing space 21 is stopped, sublimation of the reaction products progresses, and the SiOx film 91 is etched. Further, the valves V3 and V4 are opened to fill the tank 81 with the HF gas and the N₂ gas of an amount equivalent to a discharge amount thereof during time t2 to time t4, and to fill the tank 82 with the basic gas and the N₂ gas of an amount equivalent to a discharge amount thereof during time t1 to time t3. Accordingly, the first storage process and the second storage process are performed again. Thereafter, the valves V3 and V4 are closed, and at time t5, which is a time after elapse of a predetermined time from time t4, the valve V2 is opened like at time t1, and the gases in the tank 82 are supplied to the processing space 21.

Subsequently, at time t6, which is 0.3 seconds after time t5, the valve V1 is opened like at time t2 and gases in the tank 81 is supplied to each processing space 21. At time t7, which is 0.2 seconds after time t6, the valve V2 is closed and the supply of gases from the tank 82 to each processing space 21 is stopped. Subsequently, at time t8, which is, for example, 0.3 seconds after time t7, the valve V1 is closed and the supply of gases from the tank 82 to each processing space 21 is stopped. As each gas is supplied as described above, sublimation of the reaction products progresses, and the SiOx film 91 is further etched. Further, the tanks 81 and 82 are filled again with the gases of an amount equivalent to a discharge amount thereof. Thereafter, the valve V2 is opened again at time t9. Therefore, when processing operations of the apparatus from time t1 to immediately before time t5 is defined as a first cycle, a second cycle, which is the same as the first cycle, is performed from time t5 to immediately before time t9, and the SiOx film 91 is etched. Even after time t9, the same cycle is repeated, and etching progresses every execution of the cycle.

When a predetermined amount of SiOx film 91 is etched by repeating the cycle a predetermined number of times and the wafer W reaches the state shown in FIG. 6, the wafer W is unloaded from the etching apparatus 1 in a reverse order of loading the wafer W. Compared to the case in which processing is performed such that the supply periods of the HF gas and the basic gas coincide with each other as described with reference to FIG. 2, in each cycle, the reactions at the central portion of the wafer W are suppressed as described above and the reactions at the peripheral portion of the wafer W are promoted. As a result, as shown in the evaluation tests to be described later, the difference in the etching amounts between the central portion and the peripheral portion of the wafer W is suppressed, and the SiOx film 91 is etched with high in-plane uniformity in the wafer W.

Each of time t1 to time t3 and time t5 to time t7, during which the basic gas is supplied to the processing container 11, is a second period. Time t1 and time t5 are start points of the second period, and time t3 and time t7 are end points of the second period. Supplying the basic gas to the processing container 11 in the second period is a second supply process. Each of time t2 to time t4 and time t6 to time t8, during which the halogen-containing gas is supplied to the processing container 11, is a first period. Time t2 and time t6 are start points of the first period, and time t4 and time t8 are end points of the first period. Supplying the halogen-containing gas to the processing container 11 in the first period is a first supply process. Therefore, in the above-described processing, etching is performed such that a start point of one of the first period and the second period is earlier than a start point of the other of the first period and the second period, and an end point of one of the first period and the second period is earlier than an end point of the other of the first period and the second period. Each of time t2 to time t3 and time t6 to time t7 is an overlapping period in which the first period and the second period overlap with each other.

By appropriately adjusting a relationship between the supply period of the HF gas and the supply period of the basic gas, it is possible to adjust a position at which the HF gas and the basic gas are mixed relatively significantly in the radial direction of the wafer W, as described with reference to FIG. 3. That is, it is possible to control a position at which etching progresses relatively significantly in the radial direction of the wafer W. By using the aforementioned method, it is also possible to make the etching amount at the peripheral portion greater than that at the central portion of the wafer W, without being limited to matching the etching amounts in the central portion and the peripheral portion of the wafer W with each other. In addition, as shown in the evaluation tests, it is also possible to further increase the etching amount at the central portion of the wafer W by setting the supply periods of the HF gas and the basic gas to be offset from each other, compared to a case in which the supply periods of the HF gas and the basic gas are set to coincide with each other. Therefore, the present disclosure can control an in-plane etching distribution in the wafer W.

In the aforementioned processing example, between the HF gas and the basic gas, the basic gas is supplied first in the same cycle, but the HF gas may be supplied first. However, considering results of the evaluation tests to be described later, the basic gas may be supplied first.

In addition, although TMA gas is used as the amine gas in the aforementioned processing, amine gases other than TMA gas may be used. Specifically, various amine compound gases such as dimethylamine, dimethylethylamine, diethylamine, triethylamine, mono-tert-butylamine, pyrrolidine, and pyridine may be used. Therefore, any of primary, secondary, or tertiary amines may be used as the etching gas.

A mixed gas of NH₃ gas and an amine gas is used as the basic gas in order to increase uniformity of etching in the grooves 93 when etching the SiOx film 91 in the grooves 93. In more detail, when etching the SiOx film 91 in the grooves 93 using the NH₃ gas only between the NH₃ gas and the amine gas, the etching amount of the SiOx film 91 tends to increase in a vicinity of an interface with the Si film 92. The reason is considered to be that the AFS generated from SiOx, NH₃, and HF is hardly adsorbed to Si. Since a thickness of the AFS layer formed on the SiOx film 91 is relatively thin in the vicinity of the interface and relatively thick at a position relatively distanced from the interface, the etching gas is easily brought into contact with the SiOx film 91 in the vicinity of the interface, which facilitates progress of the etching.

On the other hand, when etching the SiOx film 91 using the amine gas only between the NH₃ gas and the amine gas, the etching amount of the SiOx film 91 tends to increase at a position relatively distanced from the interface with the Si film 92. The reason is because a product generated from SiOx, amine, and HF has a relatively low sublimation temperature and hardly inhibits the etching gas from being brought into contact with the SiOx film 91 in the grooves 93. Therefore, it is considered that since a probability of a gas colliding with the SiOx film 91 is high at a position distanced from the Si film 92, the etching is facilitated at the position relatively distanced from the interface with the Si film 92.

As described above, in the etching apparatus 1, the etching amounts in the vicinity of the interface and at the position relatively distanced from the interface are balanced by using a difference in sublimability between reaction products generated from the NH₃ gas and the amine gas, respectively. However, the etching may be performed using only one of the NH₃ gas and the amine gas. In the above example, the SiOx film 91 in the recess that is open upward is etched, but a SiOx film 91 in a recess that is open laterally may be etched. Further, the SiOx film is not limited to a SiOx film 91 in a recess, and for example, a SiOx film 91 formed on a flat surface may be etched.

An etching target is not limited to a SiOx film, and a silicon film containing oxygen, other than the SiOx film, may be etched. Specifically, for example, a SiOCN film may be etched. In addition, a silicon oxide film formed by using tetraethyl orthosilicate gas as a raw material may be etched. The term “a film or a gas containing a component” used in this specification means that the film or the gas contains the component as a main component, and does not mean that the film or the gas contains the component as impurities. In addition, for example, a Si film may be etched.

The etching gas may be appropriately selected according to a material of an etching target film. In a case of etching a SiOx film, for example, as the halogen-containing gas, various gases other than HF, such as HCl, HBr, HI, and SF₆, may be used. In a case of etching a Si film, for example, the tank 81 is filled with F₂ gas as a halogen gas, the tank 82 is filled with NH₃ gas as the basic gas, and the same processing as in the case of etching the SiOx film 91 is performed. Instead of the F₂ gas, a halogen-containing gas such as IF₇ gas, IF₅ gas, CIF₃ gas, or SF₆ gas may be used.

A processing temperature of the wafer W may be appropriately set according to the etching target film and the etching gas used. Specifically, the processing temperature is set to a temperature at which a product generated from the etching target film and the etching gas is sublimated and the etching target film is etched. In the case of etching the Si film using F₂ gas and NH₃ gas as described above, the processing temperature of the wafer W may be set to, for example, −50 degrees C. to 150 degrees C.

As described above, as the etching target film, a silicon-containing film, such as a SiOx film or a Si film, may be selected. The present disclosure can be applied to any process, in which both a first etching gas and a second etching gas react with a film on a surface of a wafer W to generate a reaction product and the reaction product is removed by vaporization (including sublimation) to perform etching. The present disclosure is not limited to the examples described in this specification.

In addition, in the process shown in the time chart of FIG. 4, the cycle is repeated a plurality of times, but when a required etching amount is small, the cycle may be performed only once without being repeated. In the example shown in the time chart, the HF gas and the basic gas are supplied so that the supply period of the HF gas and the supply period of the basic gas overlap with each other, but these supply periods may not overlap with each other. That is, supplying one of the HF gas and the basic gas may be started after supplying the other of the HF gas and the basic gas is completed, or supplying one of the HF gas and the basic gas may be started simultaneously with completion of supplying the other of the HF gas and the basic gas. However, since there is a concern that the gases are not mixed at the peripheral portion of the wafer W and the etching amount at the peripheral portion becomes insufficient, the supply periods of the gases may be set to overlap with each other.

It is to be noted that the embodiment disclosed herein is exemplary in all respects and is not restrictive. The above-described embodiment may be omitted, replaced, modified, or combined in various forms without departing from the scope and spirit of the appended claims.

### [Evaluation Tests]

Evaluation Tests 1 to 3 performed in relation to the present disclosure will be described below. Etching was performed for wafers W each having a SiOx film formed on a surface thereof by using the etching apparatus 1. Further, with respect to each wafer W after the etching, etching amounts of the SiOx film at a plurality of different positions in the surface of the wafer W were measured. The etching was performed by executing a predetermined number of times a cycle for supplying the gases described in the embodiment, but a relationship between the supply period of the HF gas and the supply period of the basic gas (NH₃ gas+TMA gas) in the same cycle was changed for each wafer W. The SiOx films to be etched in the evaluation tests were flat films formed on the wafers W having flat surfaces, unlike the film shown in the embodiment.

In Evaluation Test 1 (1-1 to 1-5), etching was performed so that a start point of supplying the basic gas (NH₃ gas+TMA gas) and a start point of supplying the HF gas coincide with each other in the same cycle. In Evaluation Test 2 (2-1 to 2-5), etching was performed so that an end point of supplying the basic gas and an end point of supplying the HF coincide with each other in the same cycle. In Evaluation Test 3 (3-1 to 3-3), etching was performed so that in the same cycle, a start point of supplying the basic gas and a start point of supplying the HF gas do not coincide with each other and an end point of supplying the basic gas and an end point of supplying the HF gas do not coincide with each other. In Evaluation Test 3, a supply period of the HF gas and a supply period of the basic gas in the same cycle were set to have the same length. In each evaluation test, a predetermined time interval was set after a stop of supplying both the HF gas and the basic gas into the processing container 11 in one cycle and before a start of a next cycle, so that a reaction product is sublimated. That is, when the gases were supplied as shown in the chart in FIG. 4, a predetermined time interval was set for a period of time from time t4 to time t5.

In Evaluation Tests 1 to 3, an index value of in-plane uniformity of etching was obtained from an etching amount at each position in the surface of the wafer W. This index value is a value (unit: %) obtained by calculating 3 of the obtained etching amounts, dividing the calculated value by an average value of the etching amounts, and multiplying the divided value by 100. The index value decreases as the uniformity of the etching amounts in the surface of the wafer W increases. In addition, an image of an etching distribution in the surface of the wafer W was created from the etching amount at each position in the surface of the wafer W. This image of the etching distribution is an image of the wafer W to which a color gradation by computer graphics is applied, and represents an etching amount at an arbitrary position in the surface of the wafer W by a color according to the etching amount.

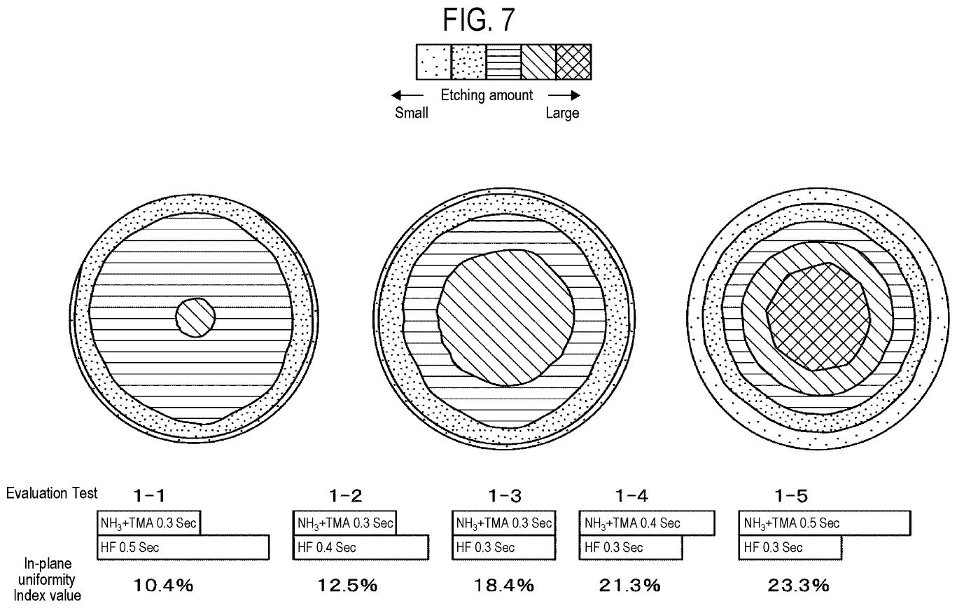

FIGS. 7, 8, and 9 show results of Evaluation Tests 1, 2, and 3, respectively, and are schematic diagrams of the wafers W corresponding to the images of the etching distributions described above. In each schematic diagram, the surface of the wafer W is divided into regions by contour lines according to colors of the image assigned to the wafer W, and an etching distribution is represented by assigning different hatchings to the divided regions. That is, different hatchings are assigned to represent different predetermined ranges of the etching amount, respectively. In addition, since the hatchings are assigned individually for each of Evaluation Tests 1, 2, and 3, even when the same hatching appears in Evaluation Tests 1 to 3, the range of the etching amount represented by the hatching are different among Evaluation Tests 1 to 3.

Two bars shown in each evaluation test of FIGS. 7 to 9 represent the supply period of the HF gas and the supply period of the basic gas in one cycle, respectively, and the HF gas and the basic gas were supplied to the processing container 11 for time periods corresponding to lengths of the bars, respectively. In each bar, a time becomes earlier as it goes leftward. A period during which the two bars overlap with each other vertically is a period during which both the HF gas and the basic gas are supplied into the processing container 11. A period during which the two bars do not overlap with each other is a period during which only one of the HF gas and the basic gas is supplied into the processing container 11.

Evaluation Test 1 (1-1 to 1-5) will now be described in detail with reference to FIG. 7. In Evaluation Test 1, etching was performed so that the start point of supplying the HF gas and the start point of supplying the basic gas coincide with each other in the same cycle. In Evaluation Tests 1-1, 1-2, 1-3, 1-4, and 1-5, durations of supplying the basic gas were 0.3 seconds, 0.3 seconds, 0.3 seconds, 0.4 seconds, and 0.5 seconds, respectively, and durations of supplying the HF gas were 0.5 seconds, 0.4 seconds, 0.3 seconds, 0.3 seconds, and 0.3 seconds, respectively. Therefore, the duration of supplying the basic gas relative to the duration of supplying the HF gas increased in the order of Evaluation Tests 1-1, 1-2, 1-3, 1-4, and 1-5. The results show that the index value of in-plane uniformity of etching increased (i.e., in-plane uniformity decreased) as the duration of supplying the basic gas increased relatively. Specifically, the index values of the in-plane uniformity of etching in Evaluation Tests 1-1, 1-2, 1-3, 1-4, and 1-5 were 10.4%, 12.5%, 18.4%, 21.3%, and 23.3%, respectively.

In the etching distribution of Evaluation Test 1, the etching amount varied in the radial direction of the wafer W, and the etching amount was greater at the central portion of the wafer W than at the peripheral portion of the wafer W. In FIG. 7, among the etching distributions of Evaluation Tests 1-1 to 1-5, the etching distributions of Evaluation Tests 1-1, 1-3, and 1-5 are shown as representative examples. In addition, the etching amount at the central portion with respect to the peripheral portion of the wafer W increases, as the duration of supplying the HF gas relative to the duration of supplying the basic gas decreases.

In Evaluation Test 1-3, the supply period of the HF gas and the supply period of the basic gas coincided with each other, and the gases were supplied as described with reference to FIG. 2. In Evaluation Tests 1-1 and 1-2 in which the supply periods of the HF gas were longer than the supply periods of the basic gas, and in which supplying the HF gas continued even after supplying the basic gas was stopped, the index values of the in-plane uniformity of etching were smaller than that in Evaluation Test 1-3, and thus the etching amount at the central portion with respect to the peripheral portion of the wafer W was suppressed. Therefore, from Evaluation Test 1, it was found that, in order to perform etching with high in-plane uniformity in the wafer W, supplying the HF gas may continue even after supplying the basic gas was stopped. In addition, from the results of Evaluation Tests 1-3 to 1-5, it was found that, in order to increase the etching amount at the central portion of the wafer W, supplying the basic gas may continue even after supplying the HF gas was stopped.

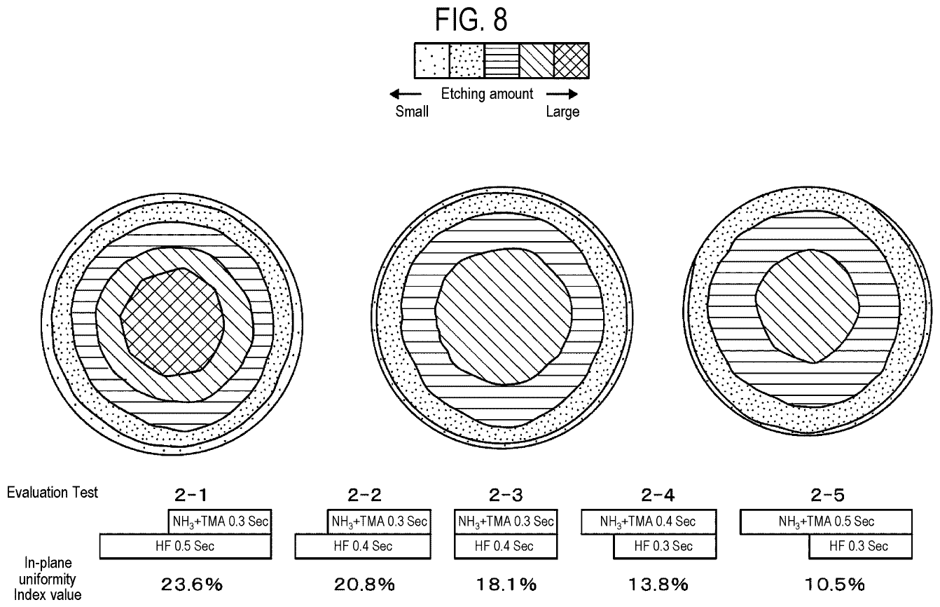

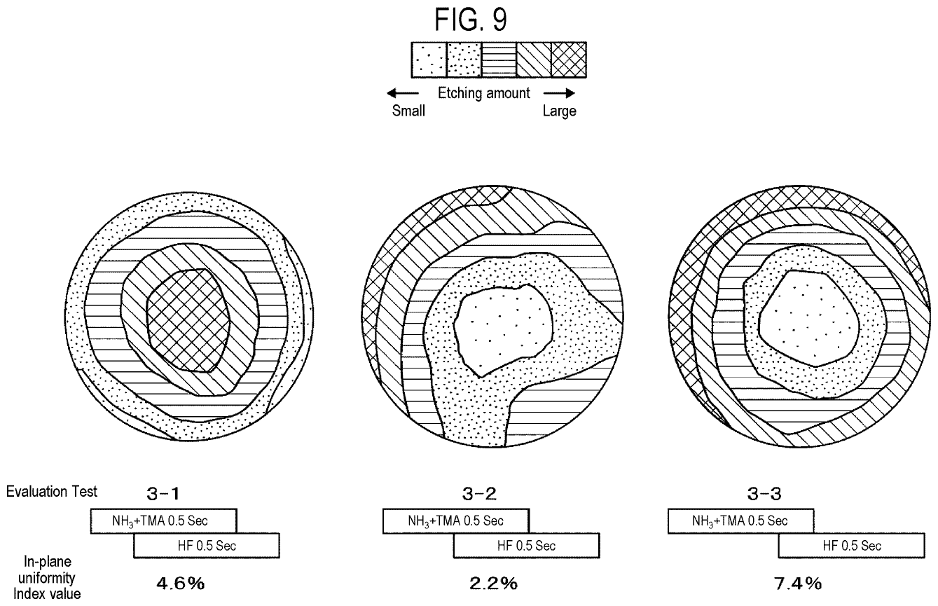

Next, Evaluation Test 2 (2-1 to 2-5) will now be described in detail with reference to FIG. 8. In Evaluation Test 2, etching was performed so that an end point of supplying the HF gas and an end point of supplying the basic gas coincide with each other in the same cycle. In Evaluation Tests 2-1, 2-2, 2-3, 2-4, and 2-5, the durations of supplying the basic gas were 0.3 seconds, 0.3 seconds, 0.3 seconds, 0.4 seconds, and 0.5 seconds, respectively, and durations of supplying the HF gas were 0.5 seconds, 0.4 seconds, 0.3 seconds, 0.3 seconds, and 0.3 seconds, respectively.

Therefore, the durations of supplying the basic gas relative to the durations of supplying the HF gas increased in the order of Evaluation Tests 2-1, 2-2, 2-3, 2-4, and 2-5. The results show that the index value of in-plane uniformity of etching decreased (i.e., in-plane uniformity increased) as the duration of supplying the basic gas increased. Specifically, the index values of the in-plane uniformity of etching in Evaluation Tests 2-1, 2-2, 2-3, 2-4, and 2-5 were 23.6%, 20.8%, 18.1%, 13.8%, and 10.5%, respectively.

In the etching distribution of Evaluation Test 2, the etching amount varied in the radial direction of the wafer W, and the etching amount was greater at the central portion of the wafer W than at the peripheral portion of the wafer W. In FIG. 8, among the etching distributions of Evaluation Tests 2-1 to 2-5, the etching distributions of Evaluation Tests 2-1, 2-3, and 2-5 are shown as representative examples. As the duration of supplying the HF gas relative to the duration of supplying the basic gas increased, the etching amount at the central portion with respect to the peripheral portion of the wafer W increased.

In Evaluation Test 2-3, the supply period of the HF gas and the supply period of the basic gas coincided with each other, and the gases were supplied as described with reference to FIG. 2. In Evaluation Tests 2-4 and 2-5 in which the supply periods of the basic gas were longer than the supply periods of the HF gas, and in which supplying the basic gas was started before supplying the HF gas was started, the index values of the in-plane uniformity of etching were smaller than that in Evaluation Test 2-3, and thus the etching amount at the central portion with respect to the peripheral portion of the wafer W was suppressed. Therefore, from Evaluation Test 2, it was found that, in order to perform etching with high in-plane uniformity in wafer W, supplying the basic gas may be started before supplying the HF gas was started. From the results of Evaluation Tests 2-1 to 2-3, it was found that, in order to increase the etching amount at the central portion of the wafer W, supplying the HF gas may be started before supplying the basic gas was started.

Next, Evaluation Test 3 (3-1 to 3-3) will be described with reference to FIG. 9. In Evaluation Test 3, based on the results of Evaluation Tests 1 and 2, in order to further increase in-plane uniformity of etching in the wafer W, supplying the basic gas was started before supplying the HF gas was started, and supplying the HF gas continued even after supplying the basic gas was stopped. As described above, since the lengths of the duration of supplying the HF gas and the duration of supplying the basic gas are the same to each other, supplying the gases was performed so that the supply period of the HF gas and the supply period of the basic gas were offset from each other in Evaluation Test 3, and an amount of offset was set to be different among Evaluation Tests 3-1 to 3-3.

In Evaluation Tests 3-1, 3-2, and 3-3, the duration of supplying the HF gas and the duration of supplying the basic gas in one cycle were set to 0.5 seconds. In Evaluation Tests 3-1, 3-2, and 3-3, processing was performed so that the start point of supplying the HF gas was delayed by 0.2 seconds, 0.3 seconds, and 0.4 seconds, respectively, relative to the start point of supplying the basic gas. A relationship between a supply time of the HF gas and a supply time of the basic gas in Evaluation Test 3-2 is the same as the relationship shown in the time chart of FIG. 4.

In Evaluation Test 3 as well, the etching amount in the etching distribution varied in the radial direction of the wafer W. However, a magnitude relationship between the etching amount at the central portion and the etching amount at the peripheral portion were different among Evaluation Tests 3-1 to 3-3. Specifically, in Evaluation Test 3-1, the etching amount was greater at the central portion of the wafer W than at the peripheral portion of the wafer W, which was the same as in Evaluation Tests 1 and 2. However, in Evaluation Tests 3-2 and 3-3, the etching amount was greater at the peripheral portion of the wafer W than at the central portion of the wafer W. In addition, in Evaluation Tests 3-1, 3-2, and 3-3, the index values of the in-plane uniformity of etching were 4.6%, 2.2%, and 7.4%, respectively, which indicates that the in-plane uniformity was than those of Evaluation Tests 1 and 2.

From the results of Evaluation Tests 1 to 3, it was found that, by setting the supply period of the HF gas and the supply period of the basic gas to be offset from each other, the etching amount at the central portion of the wafer W can be increased compared to the case in which the supply periods coincide with each other, or the difference in the etching amounts between the central portion and the peripheral portion can be suppressed to improve the in-plane uniformity of etching. Further, it was found that, by adjusting the relationship between the supply period of the HF gas and the supply period of the basic gas, the magnitude relationship between the etching amount at the central portion and the etching amount at the peripheral portion in the surface of the wafer W can be switched. In addition, it was confirmed that, in order to improve in-plane uniformity of etching in the wafer W, supplying the basic gas may be started before supplying the HF gas is started and supplying the HF gas may continue even after supplying the basic gas is stopped. That is, it was confirmed that etching may be performed such that a start point of one of the first period and the second period is earlier than that of the other of the first period and the second period, and an end point of one of the first period and the second period is earlier than that of the other of the first period and the second period.

Under each processing condition of Evaluation Tests 1 to 3, the SiOx films 91 in the grooves 93 formed on the Si film 92 as described with reference to FIG. 5 was etched, and a shape of each film after the etching was observed. As a result, it was confirmed that etching was performed with high selectivity with respect to the Si film 92, as shown in FIG. 6. Therefore, it was confirmed that, even when the supply periods of the HF gas and the basic gas do not coincide with each other, the etching profile is prevented from deviating from a desired profile.

According to the present disclosure, it is possible to control an etching distribution on a surface of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method comprising:
accommodating a substrate, which has a surface to be etched by a reaction generated by supplying both a first etching gas and a second etching gas, in a processing container;
a first storage process of supplying the first etching gas from a first gas supply to a first gas supply path and storing the first etching gas in a first storage provided in the first gas supply path to increase an internal pressure of the first storage;
a second storage process of supplying the second etching gas from a second gas supply to a second gas supply path and storing the second etching gas in a second storage provided in the second gas supply path to increase an internal pressure of the second storage;
a first supply process of supplying the first etching gas from the first storage into the processing container in a first period; and
a second supply process of supplying the second etching gas from the second storage into the processing container in a second period, wherein at least one of a start point or an end point of the second period is set to be respectively different from at least one of a start point or an end point of the first period so that there is a period during which only one of the first etching gas and the second etching gas is supplied into the processing container.

2. The etching method of claim 1, wherein a length of each of the first period and the second period is one second or less.

3. The etching method of claim 2, wherein an overlapping period in which the first period and the second period overlap with each other is formed.

4. The etching method of claim 3, wherein the start point of one of the first period and the second period is earlier than the start point of the other of the first period and the second period, and
wherein the end point of one of the first period and the second period is earlier than the end point of the other of the first period and the second period.

5. The etching method of claim 4, wherein the length of the first period and the length of the second period are equal to each other.

6. The etching method of claim 1, wherein the first supply process and the second supply process are repeated to repeatedly etch the surface of the substrate; and
wherein the method further includes exhausting an interior of the processing container, after execution of the first supply process and the second supply process and before a next execution of the first supply process and the second supply process.

7. The etching method of claim 1, wherein the first etching gas is a halogen-containing gas, the second etching gas is a basic gas, and the surface of the substrate to be etched is formed by a silicon-containing film.

8. The etching method of claim 7, wherein the silicon-containing film is a silicon oxide film.

9. An etching apparatus comprising:
a processing container configured to accommodate a substrate having a surface to be etched by a reaction generated by supplying both a first etching gas and a second etching gas;
a first gas supply path to which the first etching gas is supplied from a first gas supply;
a first storage provided in the first gas supply path, and configured to store the first etching gas to increase an internal pressure of the first storage;
a second gas supply path to which the second etching gas is supplied from a second gas supply;
a second storage provided in the second gas supply path, and configured to store the second etching gas to increase an internal pressure of the second storage;
a first valve provided on a downstream side of the first storage in the first gas supply path, and configured to be open to supply the first etching gas from the first storage into the processing chamber in a first period; and
a second valve provided on a downstream side of the second storage in the second gas supply path, and configured to be open to supply the second etching gas from the second storage into the processing chamber in a second period, wherein at least one of a start point or an end point of the second period is set to be respectively different from at least one of a start point or an end point of the first period so that there is a period during which only one of the first etching gas and the second etching gas is supplied into the processing container.
